(19) United States
(12) Patent Application Publication
(10) Pub. No.: US 2005/0280134 A1
(43) Pub. Date: Dec. 22, 2005

(54) Multi-frequency noise suppression capacitor set

(75) Inventors: David Gibson, Lake Oswego, OR (US); Andy Stavros, San Jose, CA (US); Michael Warner, San Jose, CA (US)

Correspondence Address: LERNER DAVID et al.;TESSERA, 600 SOUTH AVENUE WEST, WESTFIELD, NJ, 07090, US

(73) Assignee: Tessera, Inc., San Jose, CA (US)

(21) Appl. No.: 11/154,395

(22) Filed: Jun. 16, 2005

Related U.S. Application Data
(60) Provisional application No. 60/581,279, filed on Jun. 18, 2004.

(51) Int. Cl. H01L 23/02

(52) U.S. Cl. 257/686

(57) ABSTRACT

A decoupling device (10) includes a plurality of capacitors having different capacitances (14,16,18) physically mounted in a package (12, 212), and terminals including at least one first terminal (24, 224) and at least one second terminal (26, 226) adapted for mounting the package to a circuit panel. The plural capacitors are connected in parallel between the first and second terminals so as to form plural circuits with different self-resonant frequencies. The device can be mounted as a unit on a circuit board with the first terminals connected to a power conductor and the second terminals connected to a ground conductor, and provides low impedance shunting of noise over a wide frequency spectrum.

### CROSS-REFERENCE TO RELATED APPLICATIONS

The present application claims the benefit of the filing date of U.S. Provisional Patent Application No. 60/581,279, filed Jun. 18, 2004, the disclosure of which is hereby incorporated by reference herein.

### BACKGROUND OF THE INVENTION

The present invention relates to electronic circuitry and packaging, and more particularly relates to improvements in devices for providing decoupling of components in a circuit. Electronic devices typically include multiple components connected to common power and ground conductors, which in turn are connected to a power source. Each component can draw power from these conductors. However, as each component draws power, it tends to disturb the electrical potentials prevailing on the power and ground conductors. For example, devices known as line drivers and power amplifiers can be repeatedly switched on and off. Each time such a device changes state, it creates a disturbance on the power and ground conductors, commonly referred to as “noise.” The noise propagates along the power and ground conductors, and affects other components. The noise includes components at frequencies corresponding to the switching frequency of the device, and harmonics of the switching frequency. It has long been the practice to connect a capacitor, referred to as a bypass or decoupling capacitor, between the power and ground conductors adjacent to the connections between these conductors and the noise-generating device. For example, in a circuit incorporating numerous semiconductor chips, individual decoupling capacitors may be connected between the power and ground conductors of a circuit board close to each semiconductor chip. A theoretically perfect capacitor would provide a low-impedance current pathway or shunt for any alternating signal, at any frequency. Such a low-impedance shunt would effectively attenuate any noise signal.

Unfortunately, real capacitors have inductance and resistance, as well as capacitance. In effect, a real capacitor actually constitutes an inductive-capacitive resonant circuit. For signals at and near the resonant frequency of the circuit, referred to herein as the “self-resonant frequency” or “SRF,” a real capacitor provides a low-impedance shunt as intended. However, for frequencies far from the SRF, a real capacitor presents a high-impedance current pathway. Accordingly, a single capacitor may be ineffective to attenuate noise signals having frequencies far from its SRF. Generally, larger capacitors have lower SRFs. For example, a typical 0.1 μF capacitor has an impedance versus frequency characteristic curve as shown in the logarithmic plot A of FIG. 1. For a range of about 4 MHz to about 60 MHz, 1 μF capacitor has impedance of 0.5 ohms or less; over a range of about 1.5 MHz to about 200 MHz, it has impedance of about 1 ohm or less. Such a capacitor will effectively attenuate noise signals within these ranges, particularly in the 4-60 MHz range. However, at frequencies above about 200 MHz or below about 1 MHz, such a capacitor presents a higher impedance, and thus provides less effective attenuation. By contrast, a typical 100 pF (0.0001 μF) capacitor provides impedance below about 1 ohm only over a range of about 500 MHz to about 700 MHz, as indicated by curve 12 in FIG. 1.

Many modern systems include devices which generate signals over a wide range of frequencies. For example, where a line driver or power amplifier is controlled by a microprocessor, the intervals between state changes of the line driver or power amplifier will vary with the commands issued by the microprocessor, so that the line driver or power amplifier will emit noise signals having a wide range of frequencies. Moreover, this problem is aggravated as the speed of the system clock controlling the microprocessor increases; faster clock signals imply faster voltage slew rates during transitions between states, which tend to increase the content of higher frequency harmonics in the noise signals.

In theory, it would be possible to mount multiple individual capacitors on a circuit board adjacent to each chip. However, this approach increases the cost and complexity of the assembly, in that it requires stocking and handling of numerous parts and individual mounting operations to position all of these parts on the circuit board. Moreover, this approach consumes considerable space on the circuit board, making it unsuitable for small, compact products. Also, the conductors which must be incorporated in the circuit board to make the various connections typically add self-inductance in series with the individual capacitors, which tends to their overall impedance, particularly at high frequencies. Thus, this approach may not provide satisfactory noise attenuation.

### SUMMARY OF THE INVENTION

One aspect of the present invention provides a decoupling device. The decoupling device according to this aspect of the invention preferably includes package having at least one first terminal and at least one second terminal. The package and the terminals are adapted for mounting as a unit to a circuit structure. For example, the package and terminals may be adapted for surface-mounting to a circuit board or other circuit panel. The device according to this aspect of the invention also includes a plurality of capacitors in the package. Each of these capacitors is connected between one first terminal and one second terminal so that said capacitors and the connections between said capacitors and said terminals form a plurality of circuits extending between the at least one first terminal and the at least one second terminal. The capacitors most preferably have different capacitances and the plural circuits most preferably have different self-resonant frequencies.

In use, such a decoupling device can be mounted to a circuit panel with the one or more first terminals connected to a power conductor and with the one or more second terminals connected to a ground conductor. Most desirably, these connections are made adjacent the connections between the conductors and a chip or other structure incorporating a noise-generating device. The plural circuits are thus connected in parallel between the power and ground conductors. They provide low-impedance paths for noise over a wide spectrum of frequencies.

Most preferably, the entire decoupling device occupies an area on the circuit panel equal to or just slightly larger than the area which would be occupied by a single discrete capacitor. For example, the plural capacitors can be physically stacked on one another within the package of the device. Moreover, the circuit board manufacturer need only handle and stock a single component.

### BRIEF DESCRIPTION OF THE DRAWINGS

FIG. 1 is a graph of impedance versus frequency for certain capacitors.

FIG. 2 is a circuit diagram depicting an assembly including a decoupling device in accordance with one embodiment of the invention.

FIG. 3 is a sectional elevational view depicting the decoupling device of FIG. 2.

FIG. 4 is a view similar to FIG. 3 depicting a decoupling device according to a further embodiment of the invention.

FIG. 5 is a bottom plan view depicting a decoupling device according to yet another embodiment of the invention.

FIG. 6 is a circuit diagram depicting an assembly including the decoupling device of FIG. 5.

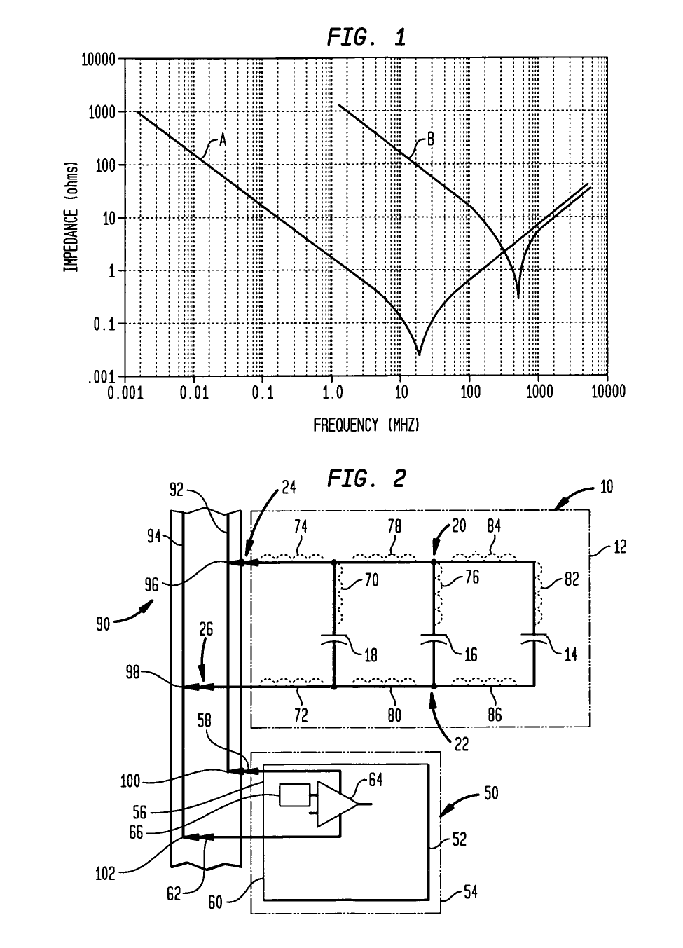

### DETAILED DESCRIPTION

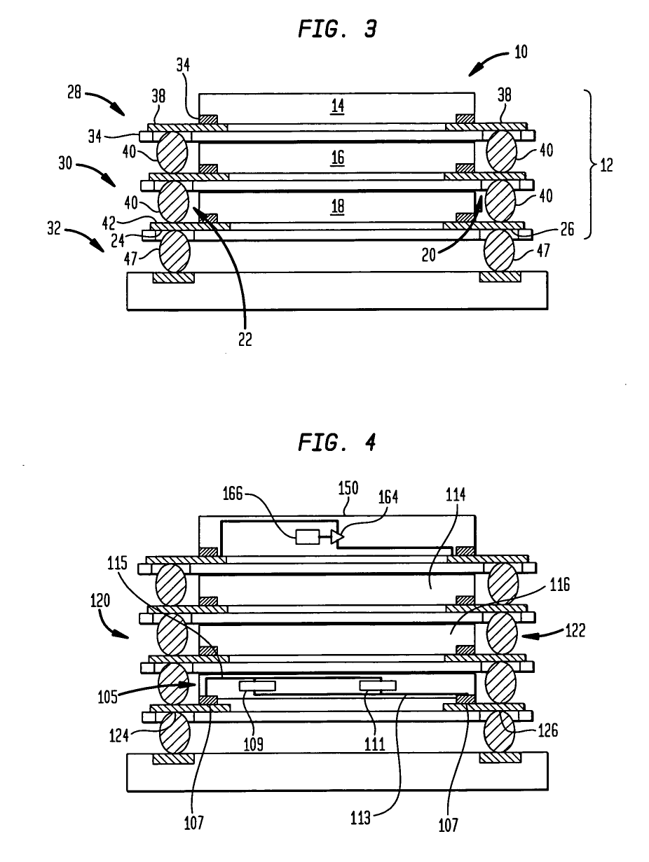

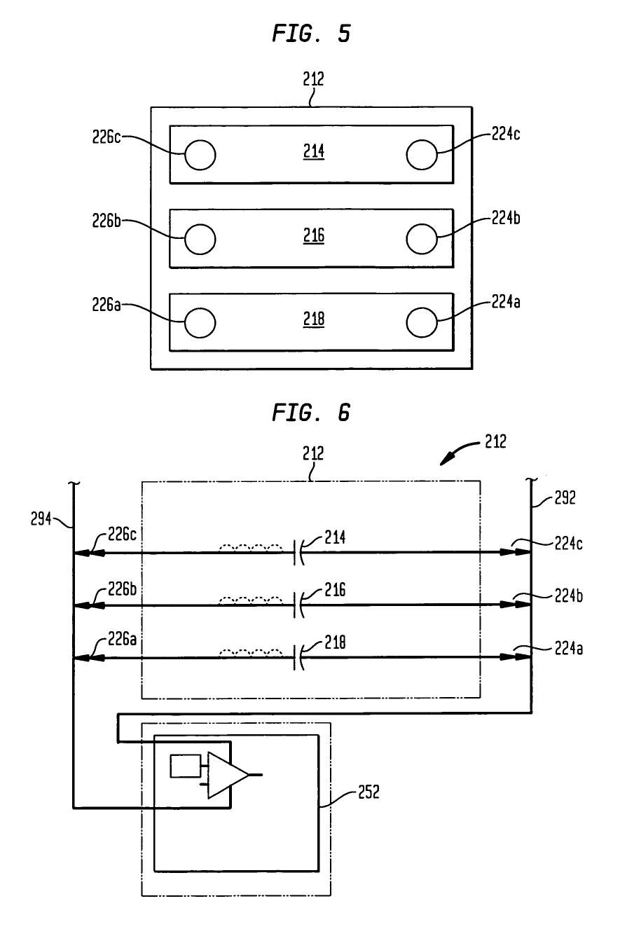

A decoupling device 10 according to one embodiment of the present invention is shown in association with other components in an electrical schematic view in FIG. 2. The physical structure of the decoupling device 10 is depicted in schematic sectional view in FIG. 3. The device includes a package 12 and a plurality of capacitors physically mounted in the package. As referred to herein, a device or component is mounted “in” a package when the device either forms part of the package or is physically attached to the package, so that the device can be handled and placed along with the package. Package 12 further includes a first bus conductor 20 and a second bus conductor 22, as well as a first terminal 24 connected to the first bus conductor and a second terminal 26 connected to the second bus conductor. In the particular embodiment illustrated, package 12 is a so-called “ball stack” package incorporating three physical units 28, 30 and 32 (FIG. 3). Unit 28 includes a dielectric substrate 34 with unit leads 36 mounted on the dielectric substrate. The unit leads 36 define unit connections 38. The unit leads 36 connect the unit connections 38 to the physical terminals of capacitor 14. Each of the other units 30 and 32 has a similar structure with unit terminals connected to capacitors 16 and 18 respectively. The units are arranged in a stack, so that the various units and the various capacitors incorporated in the individual units are superposed one above the other. The unit connections of the various units are interconnected with one another by conductive elements such as solder balls 40 disposed between adjacent units.

The unit connections 42 of the bottom unit 32 in the stack are exposed at the bottom of the stack, so that the downwardly-facing surfaces of these unit connections are available for connection to a circuit board. These downwardly-facing surfaces, thus, constitute the first and second terminals 24 and 26 of the package. The superposed unit connections and conductive elements 40 cooperatively constitute bus conductors 20 and 22. Terminals 24 and 26 are arranged and adapted for surface-mounting to a circuit board using conventional surface-mounting techniques. Thus, the terminals are arranged so that they may be connected to contact pads of a circuit panel using additional solder balls 47 or other masses of conductive bonding material. The additional solder balls or masses may be provided as a part of the package 12, or may be applied during the surface-mounting process.

The particular physical configurations of the units and stack are merely exemplary. Numerous forms of ball stack packages and related packages are used in packaging plural semiconductor chips in stacked arrangement with one another. Exemplary ball stack packages used for mounting semiconductor chips are shown in certain embodiments of the following U.S. patents and published patent applications, the disclosures of which are hereby incorporated by reference herein: U.S. Pat. No. 5,861,666; U.S. Pat. No. 6,121,676; U.S. Pat. No. 6,054,337; and 2003/0107118 A1. In other variations, each unit may consist only of the physical housing of the capacitor, with the terminals of the various capacitors connected directly to one another by conductive elements, and with the housings held together by an adhesive or by the conductive elements. In such an arrangement, the terminals of the bottom unit, consisting of the terminals of the lower-most capacitor in the stack, may constitute the package terminals. In this arrangement, the package consists of the interconnected housings of the individual capacitors.

Capacitors 18, 16 and 14 are physically arranged within the stack of FIG. 3, with the lowest value capacitor 18, having the smallest capacitance, disposed at the bottom of the stack and with the highest value 14 at the top of the stack. As best appreciated with reference to FIG. 2, the points of connection between the individual capacitors 18, 16 and 14 and the bus conductors are similarly arranged in capacitor-value order, with the points of connection of the lowest value capacitor 18 disposed closer to terminals 24 and 26 than the points of connection between the next higher value capacitor 16 and with the points of connection between the highest capacitor 14 connected to the bus conductors 22 and 20, furthest from terminals 24 and 26.

As depicted in FIG. 2, the decoupling device 10 is used in conjunction with a packaged semiconductor chip 50 which incorporates a chip 52 and a chip package to facilitate mounting and connection of the chip. Chip 52 has a power contact 56 which is connected to a power terminal 58 of the chip package 50. The chip also has a ground contact 60 which is connected to a ground terminal 62 of the chip package. The internal circuitry of the chip includes a power-using device 64 which may be a line driver, power amplifier, or other device adapted to draw power in response to signals applied by other circuitry. In the embodiment illustrated, the chip includes an internal processor 66 connected to the power-using device 64, so that processor 66 controls device 64 and actuates it to draw power at intervals determined by the program executed by processor 66. The chip includes numerous other connections and devices, which are omitted in FIG. 2 for clarity of illustration. The chip package may be of essentially any conventional configuration.

The parallel-connected capacitors 14, 16 and 18 thus define three circuits connected in parallel between first and second terminals 24 and 26. One such circuit includes capacitor 18. This circuit inherently includes the self-inductance of the capacitor itself, as indicated in broken lines at 70, as well as the self-inductances 72 and 74 of those portions of the bus conductors 20 and 22 extending between the terminals 24 and 26 and the points of connection between capacitor 18 and the bus conductors. Another circuit includes capacitor 16 and its associated self-inductance 76, as well as the self-inductances 74, 78, 72 and 80 of the bus conductor portions connecting the terminals 24 and 26 with the points of connection of capacitor 16. A third circuit includes the capacitance of capacitor 14, together with the self-inductance 82 of that capacitor and series-connected inductances 74, 78, 84, 86, 80 and 72 of the bus conductors. Each of these circuits will have a resonant frequency which depends on the values of the capacitances and inductances included in the circuit. The capacitors are selected so that these resonant frequencies differ from one another. The capacitors themselves, and the elements constituting the bus conductors, desirably are designed to minimize the inductances and resistances in the system. Most preferably, the capacitors are selected so as to provide a low aggregate AC impedance between terminals 24 and 26, desirably less than about 1 ohm and more preferably in the range of a few hundred milliohms or less for all signals within a relatively wide range, desirably from about 10 MHz or less to a few GHz or more. Although only three capacitors are illustrated in FIGS. 2 and 3 for simplicity and ease of understanding, it should be appreciated that more than three capacitors may be used to provide the desired range.

The decoupling device 10 and chip package 50 are both mounted to a circuit panel 90 having a power conductor 92 and a ground conductor 94. The first terminal 24 of the decoupling device is connected to a contact pad 96 incorporated in the power conductor, whereas the second terminal 26 is connected to a contact pad 98 incorporated in the ground conductor 94. These connections desirably are physically adjacent to the contact pads 100 and 102, which are connected to the power and ground terminals 58 and 62 of chip package 50 and hence connected to the power and ground contacts 56 and 60 of chip 52. The decoupling device thus provides effective shunting for noise signals generated by power-using device 64 incorporated in chip 52 and prevents propagation of noise signals along the power and ground conductors 92 and 94. This effective shunting action is provided without complicating the assembly process; only a single component (device 10) needs to be handled, stocked and mounted. Desirably, device 10 occupies an area on the circuit board 90 approximately the same as that which would be occupied by a single, individual capacitor. The device also simplifies design of the circuitry. The design engineer need not attempt to anticipate the various noise frequencies which may be generated in service; any noise frequency within the operating range of the decoupling device 10 will be effectively shunted.

In a variant (FIG. 4), a plurality of the capacitors are formed as portions of a unitary element referred to herein as an “integrated passives on chip” or “IPOC” 105. Typically, an IPOC is formed on or in a body of a semiconductor such as silicon or a rigid dielectric and has a shape similar to that of a conventional semiconductor chip. As depicted in FIG. 4, only two capacitors 109 and 111 are shown within the IPOC 105, but in practice a real IPOC may include more than two capacitors. The IPOC 105 itself has terminals 107 and internal conductors 113 and 177 connecting internal capacitors 109 and 111 in parallel between terminals 107. The IPOC 105 can be mounted in stacked arrangement with additional capacitors 116 and 114, so that the internal conductors 113 and 115 of the IPOC, together with the bus conductors 120 and 122, cooperatively connect the internal capacitors 109, 111 and the additional capacitors 116, 114 in parallel with one another, thereby forming plural circuits connected in parallel between the first terminal 124 and second terminal 126 substantially as discussed above. Typically, the capacitors incorporated in an IPOC have relatively small capacitance values, so that the additional capacitors 114 and 116 constitute the higher-valued capacitors in the unit.

The packaged device incorporated in FIG. 4 also has an active semiconductor chip 150 mounted in the package. In the particular embodiment depicted, the semiconductor chip 150 occupies the top-most unit in the stack of units. This chip incorporates one or more power-using devices 64, such as line drivers or power amplifiers, and controlling devices 166 similar to those discussed above with reference to FIG. 2. The power connection of the chip 150 is connected through bus conductor 120 to the first terminal 124 of the package, whereas the ground connection of the power-using device 164 within the chip is connected to the opposite bus conductor 122 and hence to the second terminal 126 of the package. The entire package, again, can be mounted to a circuit panel 190 in a single mounting step. Stated another way, both the power-using device and the decoupling device are incorporated in a single common package. The use of an IPOC as shown in FIG. 4 is not limited to devices which also incorporate the active semiconductor chip, as also shown in FIG. 4. The device of FIGS. 2 and 3, formed separately from the semiconductor chip package, may also incorporate an IPOC.

Devices according to the present invention can be arranged to provide electrical noise suppression in frequency ranges other than the particular range of about 10 MHz or less to a few GHz or more discussed above with reference to FIGS. 2 and 3. The invention can be used to suppress electrical noise over any frequency range of interest. For example, noise suppression may be provided over a frequency range that spans a few hundred MHz, e.g., from 200 MHz to 800 MHz. In some instances, noise suppression may be provided over a frequency range of at least one order of magnitude. When a plurality of capacitors of different self-resonant frequencies are properly used, noise suppression may be provided over a frequency range that spans at least two orders of magnitude, e.g., 50 MHz to about 5 GHz.

Factors that may affect the frequency range of interest include, but are not limited to the performance of the chip or other noise-generating component associated with the decoupling device. The decoupling or noise suppression device according to this aspect of the invention can be used to suppress noise from sources other than operation of semiconductor power-using devices. For instance, a circuit panel may have traces or other conductors with lengths that facilitate the production of noise spikes of particular frequencies or which act as antennas to receive externally-noise of at particular frequencies. In such a case, the frequency range of interest may comprise a plurality of disjunctive bands, wherein each band contains a frequency of a noise spike. Thus, for example, when noise of 55 MHz and 2 GHz are produced, the frequency range of interest may be comprised of a band that spans 50 MHz to 60 MHz and another band that spans 1 GHz to 3 GHz. The same approach can be used where a power amplifier or other device will be switched at a few predetermined, widely separated frequencies and will generate noise within two or more widely separated bands. Alternatively, the frequency range of interest may comprise a single continuous range.

As mentioned above, the device desirably exhibits an aggregate impedance between the first and second terminals of less than about 1 ohm over the frequency range of interest. Depending on the desired performance, the device may exhibit an impedance of less than about 0.5 ohm. For high-performance noise suppression devices, the device may exhibit an impedance of less than about 0.1 ohm. In some instances, the device may exhibit an impedance of 0.03 ohm or lower over the frequency range of interest.

Furthermore, individual circuits included in the device, or the individual capacitors, may exhibit self resonant frequencies that are substantially evenly spaced on a logarithmic scale over the frequency range of interest. For example, noise suppression may be provided over a frequency range that spans from about 50 MHz to about 5 GHz, using capacitors in parallel having resonant frequencies at 50 MHz, 500 MHz, and 5 GHz.

Certain preferred devices according to this aspect of the invention exhibits an impedance of less than 1 ohm over a frequency range of least one order of magnitude, or, even more preferably, an impedance of less than 0.1 ohm over a frequency range of two orders of magnitude.

Stacked packages other than the ball stacks discussed above may be employed. For example, as shown in co-pending, commonly assigned U.S. patent application Ser. No. 10/786,819, filed Feb. 25, 2004, the disclosure of which is hereby incorporated by reference herein, stacked packages may be formed with conductive elements formed integrally with the leads on dielectric carriers. Other pin-like conductive elements are shown in co-pending, commonly assigned U.S. Provisional Patent Application Nos. 60/533,210, filed Dec. 30, 2003; 60/533,393, filed Dec. 30, 2003; and 60/533,437, filed Dec. 30, 2003, the disclosures of which are hereby incorporated by reference herein. Units having these types of conductive elements may also be stacked to provide a stacked package.

Another form of stacked package which is commonly employed in connection with semiconductor chips is referred to herein as a “fold stack.” A fold stack includes a dielectric element which may be a flexible circuit panel having electrically-conductive traces extending along it, and having terminals connected to at least some of these traces. In chip packaging applications, the various chips to be incorporated in a stack are mounted on different areas of the circuit panel, and the circuit panel is folded so that these different areas are superposed on one another. The circuit panel may be in the form of an elongated strip which is folded to form a U-shaped or serpentine arrangement, so that the various chips are superposed over one another in a stack. Packages of this nature are shown, for example, in U.S. Pat. Nos. 6,121,676 and 6,225,688, the disclosures of which are hereby incorporated by reference herein. A similar arrangement may be used for stacking capacitors, with or without chips, in a device according to the present invention. In such a serpentine-folded stack, traces extending along the strip would form the bus conductors, and the terminals would be exposed at the bottom of the folded stack. In a variant of the stacked package disclosed in co-pending, commonly assigned U.S. patent application Ser. No. 10/077,388, filed Feb. 15, 2002, the disclosure of which is also incorporated by reference herein, the panel initially has a cruciform shape, with side panels joined to various edges of a common center panel. In this arrangement, the side panels are folded over so that they all overly the central panel. The same arrangement can be used for packaging capacitors, with or without chips, in devices according to the present invention. Many other forms of stacked packages can be utilized.

A device according to yet another embodiment of the invention includes a plurality of capacitors 218, 216, 214 mounted in a single package 212. Here, however, the capacitors are not interconnected with one another by conductors within the package. Instead, capacitor 218 defines a first terminal 224a and a second terminal 226a, both of which are exposed at the exterior of the packaged structure. The second capacitor defines a first terminal 224b and a second terminal 226b, whereas the third capacitor 214 defines another first terminal 224c and another second terminal 226c. These terminals are arranged so that all of the first terminals 224a, 224b, 224c may be aligned with and connected to contact areas on a single common power conductor 292 of a circuit board. The second terminals 226a, 226b and 226c are similarly arranged so that all of these terminals can be connected to contact areas of a ground conductor. Thus, as seen in electrical schematic in FIG. 6, when package 212 is mounted to the circuit board, all of the capacitors are connected in parallel with one another across the power and ground conductors. Here again, each capacitor is connected in a circuit which also includes the self-inductance of the capacitor. Here again, the various capacitors are selected to provide a wide range of self-resonant frequencies. As in the embodiments discussed above, the mounted package will effectively block noise generated by a power-using device incorporated in a semiconductor chip 252 connected across the power and ground conductors 292 and 294.

In the arrangements discussed above, the terminals of the package are adapted for surface-mounting. However, other types of terminals, adapted to make other types of mechanical connections with circuit boards or other circuit structures, may be employed. For example, the package may be provided with pin-type terminals which can be received in a socket; wire-type terminals suitable for mounting in via structures by soldering; or other types of connections.

As these and other variations and combinations of the features discussed above can be utilized without departing from the invention as defined by the claims, the foregoing description of the preferred embodiments should be taken by way of illustration rather than by way of limitation of the invention as defined by the claims.

### INDUSTRIAL APPLICABILITY

The present invention can be applied in construction of electronic devices.

1. A decoupling device comprising:
(a) a package having at least one first terminal and at least one second terminal, said package and said terminals being adapted for mounting as a unit to a circuit structure; and
(b) a plurality of capacitors in said package, each said capacitor being connected between one said first terminal and one said second terminal so that said capacitors and the connections between said capacitors and said terminals form a plurality of circuits extending between said at least one first terminal and said at least one second terminal, said capacitors having different capacitances and said circuits having different self-resonant frequencies.

2. The decoupling device as claimed in claim 1 wherein said at least one first terminal and said at least one second terminal include a common first terminal and a common second terminal, a plurality of said circuits extending in parallel between said common first terminal and said common second terminal.

3. The decoupling device as claimed in claim 2 wherein said plurality of circuits include a first bus conductor connected to said common first terminal and a second bus conductor connected to said common second terminal, the capacitors included in said plurality of circuits being connected between said first and second bus conductors at connection points associated with each such capacitor, the connection points being arranged along said first and second bus conductors in order according to the capacitances of the capacitors so that the connection points associated with the lowest-value capacitor are closest to said common terminals.

4. The decoupling device as claimed in claim 3 wherein said capacitors are disposed within said package in a stacked arrangement having a top and a bottom, said common terminals are disposed adjacent the bottom of the stack, and said bus conductors extend upwardly from said common terminals, and wherein said capacitors are disposed in at least partially in order within the stack, with lower-valued capacitors disposed closer to the bottom of the stack.

5. The decoupling device as claimed in claim 4 wherein said package includes a plurality of units superposed on one another, different ones of said capacitors being included in different ones of said units, and electrically conductive elements disposed between said unit substrates, said bus conductors including said conductive elements.

6. The decoupling device as claimed in claim 1 wherein said terminals are adapted for surface-mounting to a circuit panel.

7. The decoupling device as claimed in claim 1 wherein said package includes a plurality of units superposed on one another in a stack having a bottom and a top, different ones of said capacitors being included in different ones of said units, and electrically conductive elements extending between said units, said first and second terminals being disposed adjacent the bottom of the stack.

8. The decoupling device as claimed in claim 7 wherein said conductive elements include solder balls disposed between adjacent ones of said units.

9. The decoupling device as claimed in claim 7 wherein said units are at least partially arranged in order, with at least some units incorporating lower-capacitance capacitors disposed closer to the bottom of the stack than at least some units incorporating higher-capacitance capacitors.

10. The decoupling device as claimed in claim 1 wherein two or more of some of said capacitors are formed in an IPOC.

11. A semiconductor unit including an active semiconductor chip having power and ground connections and a decoupling device as claimed in claim 1, said active semiconductor chip being mounted in said package with said power connection of said chip connected to said at least one first terminal and said ground connection of said chip being connected to said at least one second terminal.

12. An assembly including a circuit panel having power and ground conductors, a semiconductor chip having power and ground connections mounted to said circuit panel with said power and ground connections connected to said power and ground conductors of said circuit panel, and a decoupling device as claimed in claim 1 mounted to said circuit panel separately from said chip, said at least one first terminal being connected to said power conductor and said at least one second terminal being connected to said ground conductor.

13. A method of providing decoupling in an electronic circuit including the steps of:
(a) mounting one or more semiconductor chips to a circuit panel and connecting power and ground connections of each said chip to power and ground conductors of the circuit panel; and
(b) mounting one or more decoupling devices to said circuit panel so that each decoupling device is mounted as a unit in a single device placement operation and so that each decoupling device provides a plurality of circuits connected between said power and ground connections, the circuits provided by each such decoupling device including different capacitances and having different self-resonant frequencies.
